(19) United States
(12) Patent Application Publication
(10) Pub. No.: US 2026/0003290 A1
(43) Pub. Date: Jan. 1, 2026

(54) PULSE WIDTH EXTENSION SYSTEM, LASER DEVICE, AND ELECTRONIC DEVICE MANUFACTURING METHOD

(71) Applicant: GIGAPHOTON INC., Tochigi (JP)

(72) Inventors: Natsuhiko KOUNO, Tochigi (JP); Takuya WARATANI, Tochigi (JP); Shinichi MATSUMOTO, Tochigi (JP)

(73) Assignee: GIGAPHOTON INC., Tochigi (JP)

(21) Appl. No.: 19/197,964

(22) Filed: May 2, 2025

(30) Foreign Application Priority Data
Jun. 26, 2024 (JP) 2024-102777

(51) Int. Cl. G03F 7/00; G01D 5/26; G02B 26/08; G02B 27/09; H01S 3/00

(52) U.S. Cl. CPC G03F 7/70025; G01D 5/26; G02B 26/0816; G02B 27/0977; G03F 7/70041; G03F 7/70575; H01S 3/0057

(57) ABSTRACT

A pulse width extension system configured to output entering pulse laser light with a pulse width thereof extended includes a pulse width extension optical system including a beam splitter and a plurality of mirrors; a case accommodating the pulse width extension optical system; at least one target allowing a part thereof irradiated with the pulse laser light to be determined; and a target moving mechanism capable of arranging the at least one target on an optical path of the pulse laser light including the pulse width extension optical system, and retracting the at least one target from the optical path.

### CROSS-REFERENCE TO RELATED APPLICATIONS

The present application claims the benefit of Japanese Patent Application No. 2024-102777, filed on Jun. 26, 2024, the entire contents of which are hereby incorporated by reference.

### BACKGROUND

### 1. Technical Field

The present disclosure relates to a pulse width extension system, a laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. In the following, a gas laser device with a narrowed spectral line width is referred to as a line narrowing gas laser device.

### LIST OF DOCUMENTS

### Patent Documents

Patent Document 1: U.S. Pat. No. 11,799,261
Patent Document 2: International Publication No. WO2022/132448
Patent Document 3: US Patent Application Publication No. 2022/0393420

### SUMMARY

A pulse width extension system, according to an aspect of the present disclosure, configured to output entering pulse laser light with a pulse width thereof extended includes a pulse width extension optical system including a beam splitter and a plurality of mirrors; a case accommodating the pulse width extension optical system; at least one target allowing a part thereof irradiated with the pulse laser light to be determined; and a target moving mechanism capable of arranging the at least one target on an optical path of the pulse laser light including the pulse width extension optical system, and retracting the at least one target from the optical path.

A laser device according to an aspect of the present disclosure includes a laser oscillator configured to output pulse laser light, and a pulse width extension system configured to output entering pulse laser light with a pulse width thereof extended. Here, the pulse width extension system includes a pulse width extension optical system including a beam splitter and a plurality of mirrors; a case accommodating the pulse width extension optical system; at least one target allowing a part thereof irradiated with the pulse laser light to be determined; and a target moving mechanism capable of arranging the at least one target on an optical path including the pulse width extension optical system, and retracting the at least one target from the optical path.

An electronic device manufacturing method according to an aspect of the present disclosure includes generating pulse laser light with pulse width extended using a laser device, outputting the pulse laser light to an exposure apparatus, and exposing a photosensitive substrate to the pulse laser light in the exposure apparatus to manufacture an electronic device. Here, the laser device includes a laser oscillator configured to output the pulse laser light, and a pulse width extension system configured to output entering pulse laser light with the pulse width thereof extended. The pulse width extension system includes a pulse width extension optical system including a beam splitter and a plurality of mirrors; a case accommodating the pulse width extension optical system; at least one target allowing a part thereof irradiated with the pulse laser light to be determined; and a target moving mechanism capable of arranging the at least one target on an optical path including the pulse width extension optical system, and retracting the at least one target from the optical path.

### BRIEF DESCRIPTION OF THE DRAWINGS

Embodiments of the present disclosure will be described below merely as examples with reference to the accompanying drawings.

FIG. 1 is a front view schematically showing the configuration of a laser device according to a comparative example.

FIG. 2 is a view of an L-OPS viewed from a V-axis direction.

FIG. 3 is a view of a pulse width extension system viewed obliquely from above.

FIG. 4 is a view of the pulse width extension system in which a first adjustment jig and a second adjustment jig are arranged, as viewed obliquely from above.

FIG. 5 is a view of the pulse width extension system according to a first embodiment viewed obliquely from above.

FIG. 6 is a view showing the configuration of a target moving mechanism according to the first embodiment.

FIG. 7 is a view showing the configuration of the target moving mechanism according to the first embodiment.

FIG. 8 is a view for explaining alignment adjustment according to the first embodiment.

FIG. 9 is a view showing a camera that images a first target and a second target.

FIG. 10 is a view showing the configuration of the target moving mechanism according to a first modification.

FIG. 11 is a view showing the configuration of the target moving mechanism according to the first modification.

FIG. 12 is a view showing the configuration of the target moving mechanism according to a second modification.

FIG. 13 is a view showing the configuration of the target moving mechanism according to the second modification.

FIG. 14 is a view showing first to fifth modifications of the first target and the second target.

FIG. 15 is a view of the pulse width extension system according to the second embodiment viewed obliquely from above.

FIG. 16 is a view of the pulse width extension system according to a third embodiment viewed obliquely from above.

FIG. 17 is a view for explaining alignment adjustment of a first optical axis according to the third embodiment.

FIG. 18 is a view for explaining alignment adjustment of a second optical axis according to the third embodiment.

FIG. 19 is a view showing first to fifth modifications of the first target and the second target.

FIG. 20 is a view showing first to fifth modifications of the first target and the second target.

FIG. 21 is a diagram schematically showing a configuration example of an exposure apparatus.

### DESCRIPTION OF EMBODIMENTS

### Contents

1. Comparative example
   1.1 Configuration
      1.1.1 Laser device
      1.1.2 Pulse width extension system
   1.2 Operation
   1.3 Problem
2. First Embodiment
   2.1 Configuration
   2.2 Operation
   2.3 Effect
   2.4 Modification of target moving mechanism
   2.5 Modification of targets
3. Second Embodiment
   3.1 Configuration
   3.2 Operation
   3.3 Effect
4. Third Embodiment
   4.1 Configuration
   4.2 Operation
   4.3 Effect
   4.4 Modification of targets
5. Modification of first to third embodiments
6. Electronic device manufacturing method

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

### 1.1 Configuration

### 1.1.1 Laser Device

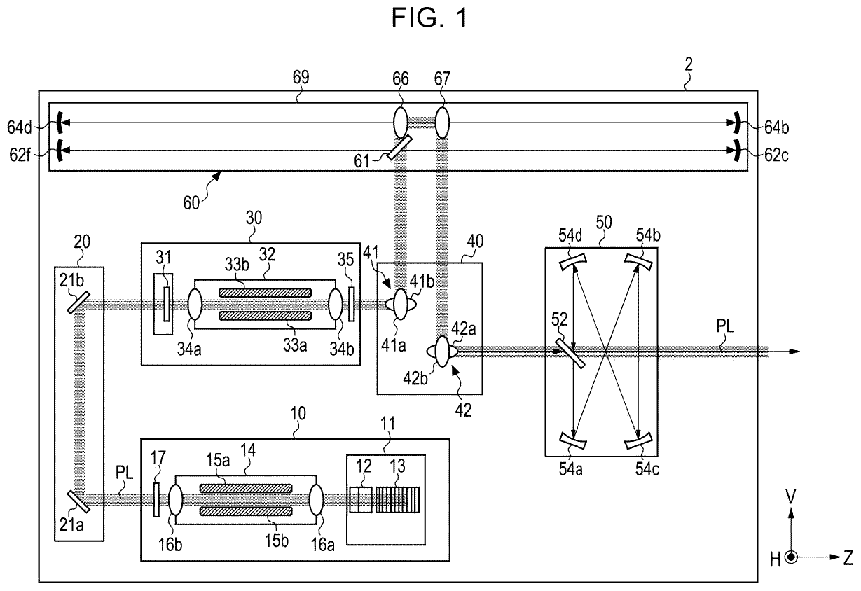

FIG. 1 schematically shows a configuration example of a laser device 2 according to a comparative example. The comparative example of the present disclosure is an example recognized by the applicant as known only by the applicant, and is not a publicly known example admitted by the applicant.

In FIG. 1, the height direction of the laser device 2 is defined as a V-axis direction, the length direction is defined as a Z-axis direction, and the depth direction is defined as an H-axis direction. For example, the V-axis direction is parallel to the gravity direction. Further, the Z-axis direction is parallel to an output direction of pulse laser light PL output from the laser device 2.

The laser device 2 is a line narrowing gas laser device including a master oscillator (MO) 10, an MO beam steering unit 20, a power oscillator (PO) 30, a PO beam steering unit 40, and an optical pulse stretcher (OPS) 50. The master oscillator 10 is an example of the “laser oscillator” according to the technology of the present disclosure.

Further, the laser device 2 includes a long optical pulse stretcher 60 (hereinafter, referred to as the “L-OPS 60”). The PO beam steering unit 40 and the L-OPS 60 configure the “pulse width extension system” according to the technology of the present disclosure. In the present disclosure, the pulse width refers to the temporal width of a pulse. Further, the L-OPS 60 is an example of the “pulse width extension optical system” according to the technology of the present disclosure.

The master oscillator 10 includes a line narrowing module (LNM) 11, a chamber 14, and an output coupling mirror (Output Coupler: OC) 17.

The LNM 11 includes a prism beam expander 12 and a grating 13 for narrowing the spectral line width. The prism beam expander 12 and the grating 13 are arranged in the Littrow arrangement so that an incident angle and a diffraction angle coincide with each other. The output coupling mirror 17 is a reflection mirror having a reflectance in the range of 40% to 60%. The output coupling mirror 17 and the LNM 11 are arranged to configure an optical resonator.

The chamber 14 is arranged on the optical path of the optical resonator. The chamber 14 includes a pair of discharge electrodes 15a, 15b and two windows 16a, 16b through which the pulse laser light PL passes. The chamber 14 contains an excimer laser gas. The excimer laser gas may include, for example, an Ar gas or a Kr gas as a rare gas, an F₂ gas as a halogen gas, and an Ne gas as a buffer gas.

The MO beam steering unit 20 includes a high reflection mirror 21a and a high reflection mirror 21b. The high reflection mirror 21a and the high reflection mirror 21b are arranged such that the pulse laser light output from the master oscillator 10 enters the power oscillator 30. The high reflection mirror of the present disclosure is a planar mirror with a high reflection film formed on a surface of a substrate formed of, for example, synthetic quartz or calcium fluoride (CaF₂). The high reflection film is a dielectric multilayer film, for example, a film containing fluoride.

The power oscillator 30 includes a rear mirror 31, a chamber 32, and an output coupling mirror 35. The rear mirror 31 and the output coupling mirror 35 are arranged to configure an optical resonator.

The chamber 32 is arranged on the optical path of the optical resonator. The chamber 32 may have a configuration similar to that of the chamber 14 of the master oscillator 10. That is, the chamber 32 includes a pair of discharge electrodes 33a, 33b and two windows 34a, 34b through which the pulse laser light PL passes. The chamber 32 contains the excimer laser gas. The rear mirror 31 is a reflection mirror having a reflectance in the range of 50% to 90%. The output coupling mirror 35 is a reflection mirror having a reflectance in the range of 10% to 30%.

The PO beam steering unit 40 includes a first steering unit 41 and a second steering unit 42 for exchanging light with the L-OPS 60. The PO beam steering unit 40 is an example of the “steering device” according to the technology of the present disclosure.

The first steering unit 41 includes a high reflection mirror 41a and a high reflection mirror 41b. The high reflection mirror 41a is arranged such that the pulse laser light output from the power oscillator 30 is reflected to be incident on the high reflection mirror 41b. The high reflection mirror 41b is arranged such that the pulse laser light PL reflected by the high reflection mirror 41a is reflected to enter the L-OPS 60. The high reflection mirrors 41a, 41b are an example of the “plurality of steering mirrors” according to the technology of the present disclosure.

The second steering unit 42 includes a high reflection mirror 42a and a high reflection mirror 42b. The high reflection mirror 42a is arranged such that the pulse laser light output from the L-OPS 60 is reflected to be incident on the high reflection mirror 42b. The high reflection mirror 42b is arranged such that the pulse laser light PL reflected by the high reflection mirror 42a is reflected to enter the OPS 50.

As will be described in detail later, the L-OPS 60 includes at least one beam splitter and a plurality of high reflection mirrors. The L-OPS 60 is arranged at a ceiling side part of the laser device 2.

The OPS 50 includes a beam splitter 52 and four concave mirrors 54a to 54d. The beam splitter 52 is arranged on the optical path of the pulse laser light PL output from the PO beam steering unit 40. The beam splitter 52 is a partial reflection mirror that transmits a part of the incident pulse laser light PL and reflects the other part thereof. The reflectance of the beam splitter 52 is preferably in the range of 40% to 70%, more preferably about 60%.

The four concave mirrors 54a to 54d configure a loop optical path through which a part of the pulse laser light PL having entered from the PO beam steering unit 40 and reflected by the beam splitter 52 is circulated and returned to the beam splitter 52. A part of the pulse laser light PL having entered from the PO beam steering unit 40 and transmitted through the beam splitter 52 is superimposed on a part of the pulse laser light PL having circulated through the loop optical path at least once and reflected by the beam splitter 52, and is output from the OPS 50.

The OPS 50 is arranged at the last stage of the laser device 2, and outputs the pulse laser light PL having the pulse width extended from the laser device 2.

Here, the OPS 50 is only required to include a beam splitter and a plurality of high reflection mirrors.

The laser device 2 may be covered with a cover panel (not shown) that can be removed for maintenance or the like.

### 1.1.2 Pulse Width Extension System

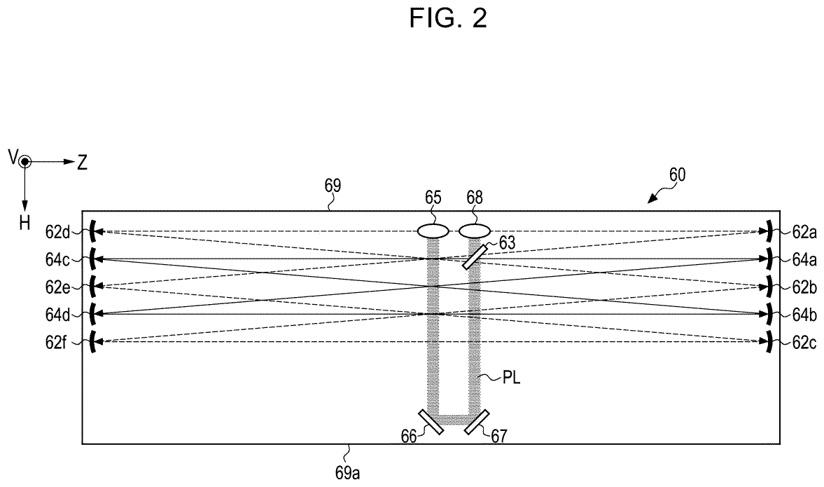

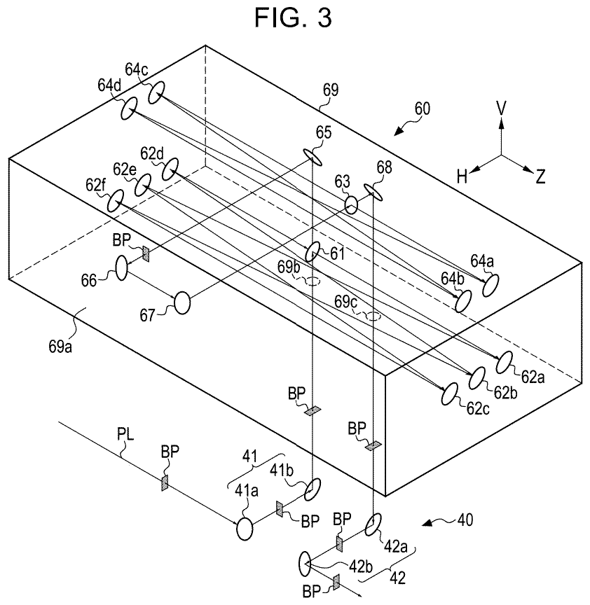

Next, the configuration of a pulse width extension system according to the comparative example will be described. FIG. 2 is a view of the L-OPS 60 viewed from the V-axis direction. FIG. 3 is a view of the pulse width extension system viewed obliquely from above.

The L-OPS 60 includes a beam splitter 61, six concave mirrors 62a to 62f, a beam splitter 63, four concave mirrors 64a to 64d, and high reflection mirrors 65 to 68. The L-OPS 60 is accommodated in a case 69. The concave mirrors 62a to 62f and the concave mirrors 64a to 64d are an example of the “plurality of mirrors” according to the technology of the present disclosure.

The case 69 is a rectangular box body whose longitudinal direction is the Z-axis direction. The case 69 includes a maintenance surface 69a. The maintenance surface 69a is a surface on which a cover panel (not shown) is opened for maintenance or the like among two surfaces opposed to each other in the H-axis direction. The inside of the case 69 is purged with a purge gas which is an inert gas. For this purpose, a purge gas supply source (not shown) may be connected to the case 69.

Further, on the bottom surface of the case 69, an opening 69b for causing the pulse laser light PL output from the first steering unit 41 to enter the case 69 and an opening 69c for outputting the pulse laser light PL toward the second steering unit 42 are provided. The openings 69b, 69c are connected to optical path pipes (not shown) purged with the purge gas.

A reference numeral BP shown in FIG. 3 indicates a beam profile of the pulse laser light PL. The first steering unit 41 is configured to rotate the beam profile BP of the incident pulse laser light PL long in the V-axis direction and output the pulse laser light PL having the beam profile BP long in the H-axis direction. The second steering unit 42 is configured to rotate the beam profile BP of the incident pulse laser light PL long in the H-axis direction and output the pulse laser light PL having the beam profile BP long in the V-axis direction.

The beam splitter 61 is arranged on the optical path of the pulse laser light PL output from the first steering unit 41. The beam splitter 61 is a partial reflection mirror that transmits a part of the incident pulse laser light PL and reflects the other part thereof. The reflectance of the beam splitter 61 is preferably in the range of 40% to 70%, more preferably about 60%.

The six concave mirrors 62a to 62f configure a first loop optical path through which a part of the pulse laser light PL having entered through the first steering unit 41 and reflected by the beam splitter 61 is circulated and returned to the beam splitter 61. In FIG. 2, the first loop optical path is indicated by broken lines. A part of the pulse laser light PL having entered from the first steering unit 41 and transmitted through the beam splitter 61 is superimposed on a part of the pulse laser light PL having circulated through the first loop optical path at least once and reflected by the beam splitter 61, and is output from the high reflection mirror 66.

The high reflection mirror 65 is arranged such that the pulse laser light PL whose pulse width is extended by the first loop optical path is reflected to be incident on the high reflection mirror 66. The high reflection mirror 66 is arranged such that the pulse laser light PL reflected by the high reflection mirror 65 is reflected to be incident on the high reflection mirror 67. The high reflection mirror 67 is arranged such that the pulse laser light PL reflected by the high reflection mirror 66 is reflected to be incident on the high reflection mirror 68.

The beam splitter 63 is arranged on the optical path of the pulse laser light PL reflected by the high reflection mirror 67. The beam splitter 63 is a partial reflection mirror that transmits a part of the incident pulse laser light PL and reflects the other part thereof. The reflectance of the beam splitter 63 is preferably in the range of 40% to 70%, more preferably about 60%.

The four concave mirrors 64a to 64d configure a second loop optical path through which a part of the pulse laser light PL having entered from the high reflection mirror 67 and reflected by the beam splitter 63 is circulated and returned to the beam splitter 63. In FIG. 2, the second loop optical path is indicated by solid lines. A part of the pulse laser light PL having entered from the high reflection mirror 67 and transmitted through the beam splitter 63 is superimposed on a part of the pulse laser light PL having circulated through the second loop optical path at least once and reflected by the beam splitter 63, and is output from the high reflection mirror 68.

The high reflection mirror 68 is arranged such that the pulse laser light PL whose pulse width is further extended by the second loop optical path is reflected to be incident on the high reflection mirror 42a of the second steering unit 42 through the opening 69c.

The concave mirrors 62a to 62f and the concave mirrors 64a to 64d are arranged at both ends in the Z-axis direction, which is the longitudinal direction of the case 69, such that the first loop optical path and the second loop optical path overlap in the V-axis direction.

The high reflection mirrors 66, 67 are arranged on the maintenance surface 69a side of the case 69, and the high reflection mirrors 65 and 68 are arranged on the side opposite to the maintenance surface 69a. Accordingly, the optical path between the high reflection mirror 65 and the first steering unit 41 and the optical path between the high reflection mirror 68 and the second steering unit 42 are arranged at the side opposite to the maintenance surface 69a.

### 1.2 Operation

Next, operation of the laser device 2 according to the comparative example will be described. When discharge occurs in the chamber 14 of the master oscillator 10, the laser gas is excited, and the pulse laser light PL line-narrowed by the optical resonator configured by the output coupling mirror 17 and the LNM 11 is output from the output coupling mirror 17. The pulse laser light PL is incident on the rear mirror 31 of the power oscillator 30 as seed light by the MO beam steering unit 20.

Discharge occurs in the chamber 32 in synchronization with the timing when the seed light transmitted through the rear mirror 31 enters. As a result, the laser gas is excited, the seed light is amplified by the Fabry-Perot optical resonator configured by the output coupling mirror 35 and the rear mirror 31, and the amplified pulse laser light PL is output from the output coupling mirror 35. The pulse laser light PL output from the output coupling mirror 35 enters the PO beam steering unit 40, and enters the L-OPS 60 with the travel direction thereof changed by the first steering unit 41.

The pulse laser light PL having entered the L-OPS 60 is extended in pulse width and returns to the PO beam steering unit 40, and enters the OPS 50 with the travel direction thereof changed by the second steering unit 42.

The pulse width of the pulse laser light PL having entered the OPS 50 is further extended, and the pulse laser light PL is output from the laser device 2. Here, the pulse laser light PL may be output from the laser device 2 via a monitor module (not shown) that measures the pulse energy, the spectral line width, the wavelength, or the like. The pulse laser light PL output from the laser device 2 enters an external apparatus such as an exposure apparatus.

By extending the pulse width of the pulse laser light PL by the L-OPS 60 and the OPS 50, the coherence is reduced. This suppresses occurrence of speckle. Speckle is light and dark spots caused by interference when pulse laser light is scattered in a random medium.

### 1.3 Problem

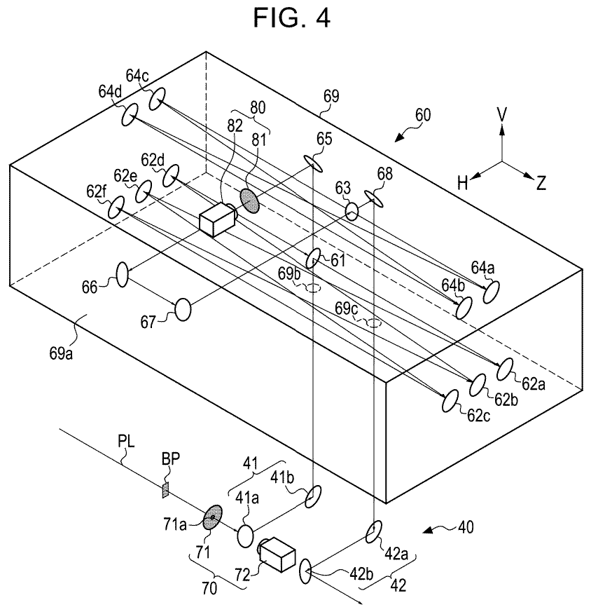

Next, a problem of the laser device 2 according to the comparative example will be described. In the laser device 2 according to the comparative example, when an abnormality occurs in the laser performance, an operator may check alignment of the optical axis on which the pulse laser light PL enters the L-OPS 60 in order to identify the cause. When misalignment occurs, the operator needs to remove the cover panel and the like of the case 69 and attach at least one adjustment jig in the case 69. For example, the operator performs alignment adjustment using a first adjustment jig 70 and a second adjustment jig 80 shown in FIG. 4. The second adjustment jig 80 is attached in the case 69 by removing the cover panel of the case 69. Hereinafter, when simply referred to as “alignment adjustment”, it also includes checking of alignment. Further, alignment adjustment includes at least one of position adjustment and angle adjustment of the optical axis.

The first adjustment jig 70 includes a first target 71 and a camera 72. The first target 71 is a circular fluorescent plate in which a pinhole 71a is formed at the center thereof, and a part irradiated with the pulse laser light PL emits fluorescence of visible light. The first target 71 is arranged such that a designed optical axis of the high reflection mirror 41a on the incident side passes through the pinhole 71a. The camera 72 is arranged at a position facing the first target 71 with the high reflection mirror 41a interposed therebetween. The high reflection mirror 41a has a property of transmitting visible light. The camera 72 receives the fluorescence emitted by the first target 71 via the high reflection mirror 41a, and thereby images the first target 71. Here, the pinhole 71a is an example of the “first passage hole” according to the technology of the present disclosure.

The operator observes an image imaged by the camera 72 in a state in which the laser device 2 outputs the pulse laser light PL. When the center of the irradiation region is deviated from the pinhole 71a, the operator adjusts the first steering unit 41 so that the center of the irradiation region coincides with the pinhole 71a. Specifically, respective angles of the high reflection mirrors 41a, 41b are adjusted. Thus, position adjustment of the beam, that is, position adjustment of the optical axis is performed using the first adjustment jig 70.

The second adjustment jig 80 includes a second target 81 and a camera 82. The second target 81 is a circular fluorescent plate, and a part irradiated with the pulse laser light PL emits fluorescence of visible light. The second target 81 is arranged such that a designed optical axis on the output side of the high reflection mirror 65 passes through the center of the second target 81. In the present comparative example, the center of the second target 81 is a target position on which a part of the pulse laser light PL having passed through the pinhole 71a is radiated. The camera 82 is arranged between the high reflection mirror 65 and the high reflection mirror 66 at a position to image the second target 81 from the output side. The operator removes the cover panel of the case 69 and arranges the second target 81 and the camera 82.

The operator observes an image imaged by the camera 82 in a state in which the laser device 2 outputs the pulse laser light PL. When the position on which a part of the pulse laser light PL having passed through the pinhole 71a of the first target 71 is radiated is deviated from the target position of the second target 81, the operator adjusts the first steering unit 41 so that the irradiation position coincides with the target position. Specifically, respective angles of the high reflection mirrors 41a, 41b are adjusted. Thus, beam pointing angle adjustment, that is, angle adjustment of the optical axis is performed using the second adjustment jig 80. As described above, in alignment adjustment of the optical axis, the optical axis is adjusted so as to pass through two predetermined points, specifically, the pinhole 71a of the first target 71 and the target position of the second target 81.

In the above-described alignment adjustment, after the cover panel is removed and the second adjustment jig 80 is arranged in the case 69, it is necessary to attach the cover panel again. Including this task, alignment adjustment may take several hours. Further, it takes more time to reseal the inside of the case 69, which has been unsealed, and purge it with the purge gas. As a result, operation time required for the alignment adjustment is long, and the upper limit of the working time allowed in a factory at which the laser device 2 is installed may be exceeded.

Therefore, there is a demand for a pulse width extension system that can complete alignment adjustment of the optical axis in a short time.

### 2. First Embodiment

The laser device 2 according to a first embodiment of the present disclosure will be described. Any component same as that described above is denoted by an identical reference sign, and duplicate description thereof is omitted unless specific description is needed.

### 2.1 Configuration

The laser device 2 according to the present embodiment has a configuration similar to that of the laser device 2 according to the comparative example except for the pulse extension system.

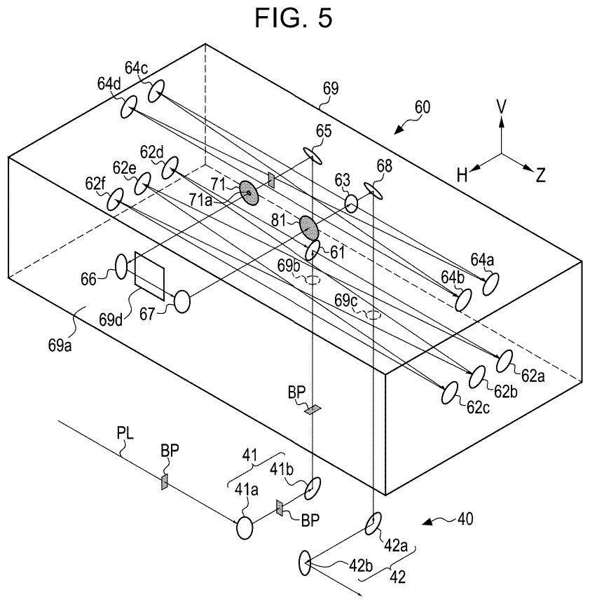

FIG. 5 is a view of the pulse width extension system according to the first embodiment viewed obliquely from above. In the present embodiment, the first target 71 and the second target 81 used for alignment adjustment are arranged in the case 69 so as to be retractable from the optical path of the pulse laser light PL. The optical system configuring the L-OPS 60 is similar to that of the comparative embodiment.

Each configuration of the first target 71 and the second target 81 is similar to that of the comparative example. The first target 71 and the second target 81 are preferably formed of synthetic quartz, and more preferably formed of borosilicate crown glass, which is generally referred to as BK7.

In the present embodiment, the first target 71 is arranged so as to be retractable from an optical path between the high reflection mirror 65 and the high reflection mirror 66. When the first target 71 is arranged on the optical path, the designed optical axis on the output side of the high reflection mirror 65 is arranged so as to pass through the pinhole 71a. Further, in the present embodiment, the second target 81 is arranged so as to be retractable from an optical path between the high reflection mirror 67 and the high reflection mirror 68. When the second target 81 is arranged on the optical path, the designed optical axis on the output side of the high reflection mirror 67 is arranged so as to pass through the center thereof. As described above, in the present embodiment, similarly to the comparative example, the first target 71 is arranged on the upstream side of the optical path of the pulse laser light PL, and the second target 81 is arranged on the downstream side thereof.

In the present embodiment, the case 69 is provided with a window 69d that allows the first target 71 and the second target 81 to be observed from the outside of the case 69. For example, the window 69d is arranged on the maintenance surface 69a side, and the high reflection mirrors 65, 68 are arranged at a region corresponding to the high reflection mirror 66 and the high reflection mirror 67 on the maintenance surface 69a side.

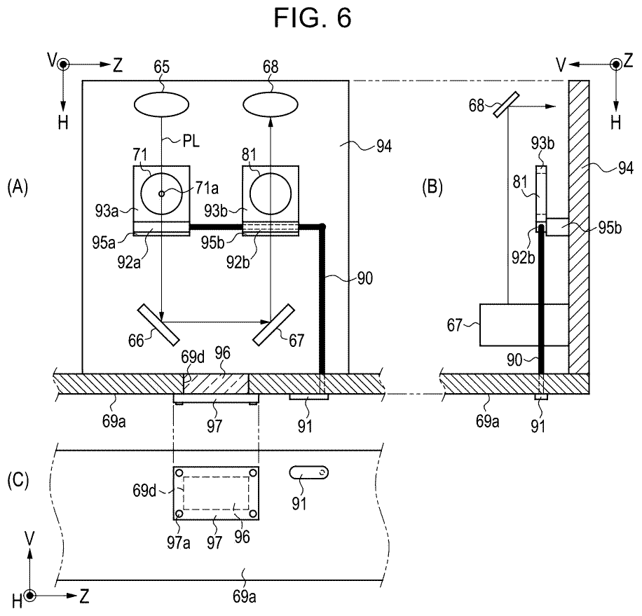

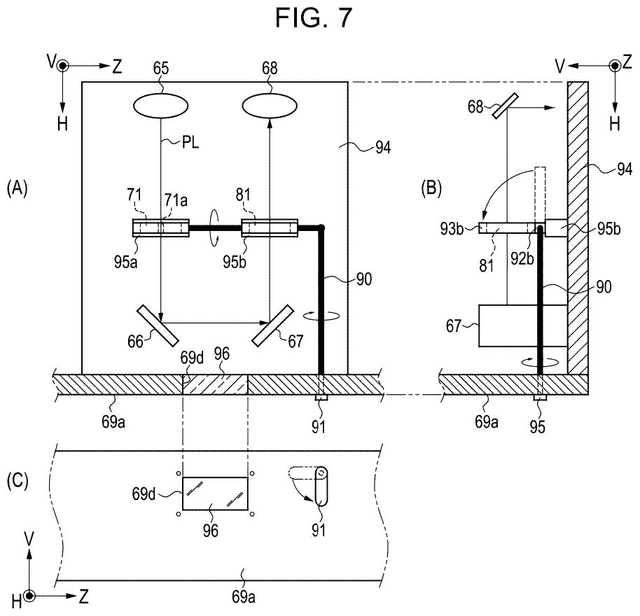

FIGS. 6 and 7 show the configuration of a target moving mechanism according to the first embodiment. FIG. 6 shows a state of the target moving mechanism under a target non-used state. FIG. 7 shows a state of the target moving mechanism under a target used state. FIGS. 6A and 7A are views of the target moving mechanism viewed from the V-axis direction. FIGS. 6B and 7B are views of the target moving mechanism viewed from the Z-axis direction. FIGS. 6C and 7C are views of the target moving mechanism viewed from the H-axis direction.

The target non-used state means that the first target 71 and the second target 81 are retracted from the optical path. The target used state means that the first target 71 and the second target 81 are arranged on the optical path. The target moving mechanism is a mechanism that enables the first target 71 and the second target 81 to be arranged on the optical path and to be retracted from the optical path.

In the present embodiment, the target moving mechanism includes a link mechanism 90. The link mechanism 90 is configured by a plurality of rod-shaped members connected to each other. The link mechanism 90 may be configured by a gear such as a bevel gear, or may be configured by another power transmission mechanism. One end of the link mechanism 90 is connected to a lever 91 provided on the maintenance surface 69a. The link mechanism 90 is configured to rotate in response to rotation operation of the lever 91 by an operator. The other end of the link mechanism 90 is joined to a first connection portion 92a and a second connection portion 92b.

The first connection portion 92a is fixed to a target holder 93a holding the first target 71. The first connection portion 92a is rotatably supported by a first support portion 95a arranged on a substrate 94. The second connection portion 92b is fixed to a target holder 93b holding the second target 81. The second connection portion 92b is rotatably supported by a second support portion 95b arranged on the substrate 94.

The link mechanism 90 transmits a drive force corresponding to rotation operation of the lever 91 to the target holders 93a, 93b, thereby moving the first target 71 and the second target 81 between a collapsed state and a raised state. As shown in FIG. 6, the first target 71 and the second target 81 are retracted from the optical path when being in the collapsed state. Further, as shown in FIG. 7, the first target 71 and the second target 81 are arranged on the optical path when being in the raised state.

The window 69d is blocked by a window plate 96 that is formed of glass, acryl, or the like and transmits visible light. Further, a cover 97 that is formed of metal or the like and blocks ultraviolet light is removably attached to the maintenance surface 69a by a plurality of bolts 97a so as to cover the window 69d. FIG. 6 shows a state in which the cover 97 is attached. FIG. 7 shows a state in which the cover 97 is removed.

### 2.2 Operation

In the present embodiment, prior to operation of the laser device 2, the first target 71 and the second target 81 are set into the collapsed state by operating the lever 91, and the cover 97 is attached so as to cover the window 69d. Operation of the laser device 2 according to the present embodiment with respect to the output of the pulse laser light PL is similar to that of the comparative example.

In the present embodiment, when abnormality occurs in the laser performance, in order to check alignment of the optical axis, the operator operates the lever 91 to set the first target 71 and the second target 81 into the raised state, so that the first target 71 and the second target 81 are arranged on the optical path. Further, the operator can observe the first target 71 and the second target 81 from the outside of the case 69 through the window 69d by removing the cover 97.

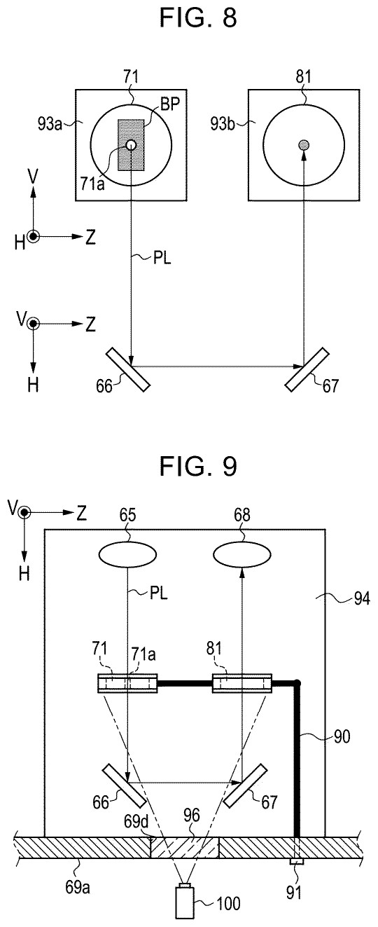

Next, the operator causes the laser device 2 to output the pulse laser light PL to visually check the position of the irradiation region of the pulse laser light PL radiated on the first target 71, as shown in FIG. 8. When the center of the irradiation region does not coincide with the pinhole 71a, the operator adjusts the first steering unit 41 so as to coincide therewith. Specifically, respective angles of the high reflection mirrors 41a, 41b are adjusted. Thus, position adjustment of the optical axis is performed.

Next, the operator visually checks the position on which a part of the pulse laser light PL having passed through the pinhole 71a of the first target 71 is radiated on the second target 81. When the irradiation position does not coincide with the target position of the second target 81, the operator adjusts the first steering unit 41 so as to coincide therewith. Specifically, respective angles of the high reflection mirrors 41a, 41b are adjusted. Thus, angle adjustment of the optical axis is performed.

When alignment adjustment is completed, the operator operates the lever 91 to set the first target 71 and the second target 81 into the collapsed state, so that the first target 71 and the second target 81 are retracted from the optical path. Further, the operator attaches the cover 97 so as to cover the window 69d.

Here, as shown in FIG. 9, the operator may attach the camera 100 to a position at which the first target 71 and the second target 81 can be imaged via the window 69d, and perform the above-described alignment adjustment while observing the imaged image by the camera 100. In this case, the operator removes the camera 100 after alignment adjustment is completed. The camera 100 is only required to be an imaging device capable of receiving fluorescence emitted by the first target 71 and the second target 81.

### 2.3 Effect

In the present embodiment, the first target 71 and the second target 81 are arranged in the case 69 so as to be retractable from the optical path of the pulse laser light PL by the target moving mechanism. Therefore, when alignment adjustment of the optical axis is performed, it is unnecessary to remove the cover panel and attach the adjustment jigs in the case 69, and to remove the adjustment jigs and attach the cover panel to the case 69 after alignment adjustment. Further, since sealing of the case 69 is not released during alignment adjustment, it is unnecessary to purge the inside of the case 69 again with the purge gas. Accordingly, according to the present embodiment, alignment adjustment can be completed in a short time.

### 2.4 Modification of Target Moving Mechanism

Next, various modifications of the target moving mechanism will be described. In the first embodiment, the target moving mechanism is a mechanism that retracts the first target 71 and the second target 81 from the optical path by setting the first target 71 and the second target 81 into the collapsed state, but various modifications are possible.

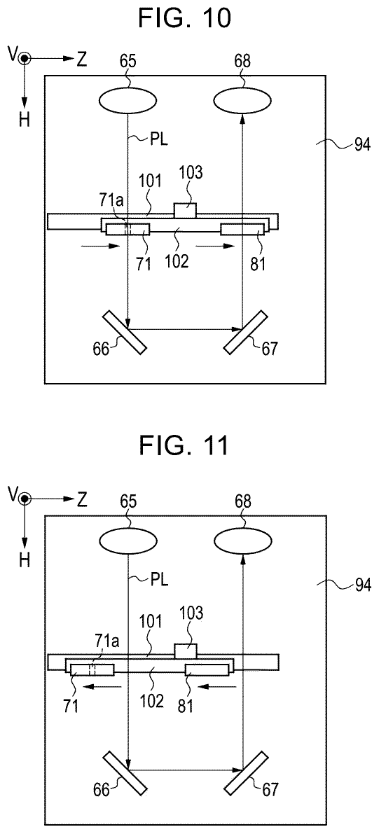

FIGS. 10 and 11 show the configuration of the target moving mechanism according to a first modification. FIG. 10 shows a state of the target moving mechanism under a target used state. FIG. 11 shows a state of the target moving mechanism under a target non-used state. In the present modification, the target moving mechanism includes a linear guide 101. The linear guide 101 is fixed on the substrate 94. The first target 71 and the second target 81 are slidably held by the linear guide 101 via a holder 102.

Further, in the present modification, an actuator 103 that slides the first target 71 and the second target 81 by driving the linear guide 101 is provided. An operation unit (not shown) for operating the actuator 103 is provided outside the case 69, and the operator slides the first target 71 and the second target 81 by operating the operation unit.

When performing alignment adjustment of the optical axis, the operator operates the operation unit to arrange the first target 71 and the second target 81 on the optical path as shown in FIG. 10. When alignment adjustment is completed, the operator operates the operation unit to retract the first target 71 and the second target 81 from the optical path as shown in FIG. 11.

The target moving mechanism may be configured to be capable of sliding the first target 71 and the second target 81 by manual operation of the operator instead of the actuator 103.

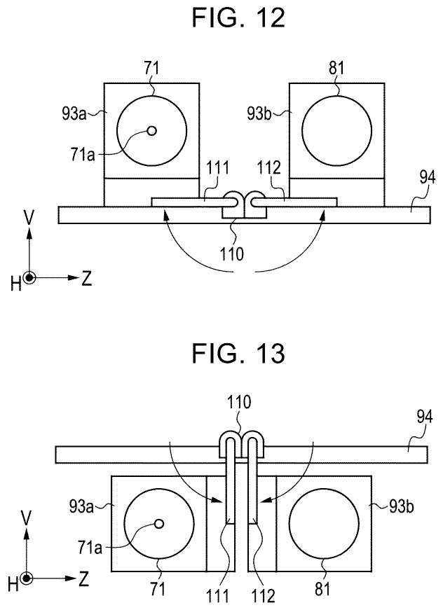

FIGS. 12 and 13 show the configuration of the target moving mechanism according to a second modification. FIG. 12 shows a state of the target moving mechanism under a target used state. FIG. 13 shows a state of the target moving mechanism under a target non-used state.

In the present modification, the target moving mechanism includes rotation arms 111, 112. The first target 71 is rotatably held by the rotation arm 111 via the target holder 93a. The second target 81 is rotatably held by the rotation arm 112 via the target holder 93b.

Further, in the present modification, an actuator 110 that rotates the first target 71 and the second target 81 by driving the rotation arms 111, 112 is provided. The rotation axes of the rotation arms 111, 112 are parallel to the optical axis. The rotation directions of the rotation arm 111 and the rotation arm 112 are opposite to each other. An operation unit (not shown) for operating the actuator 110 is provided outside the case 69, and the operator rotates the first target 71 and the second target 81 by operating the operation unit.

When performing alignment adjustment of the optical axis, the operator operates the operation unit to arrange the first target 71 and the second target 81 on the optical path as shown in FIG. 12. When alignment adjustment is completed, the operator operates the operation unit to retract the first target 71 and the second target 81 from the optical path as shown in FIG. 13. The target moving mechanism may be configured to be capable of rotating the first target 71 and the second target 81 by manual operation of the operator instead of the actuator 110.

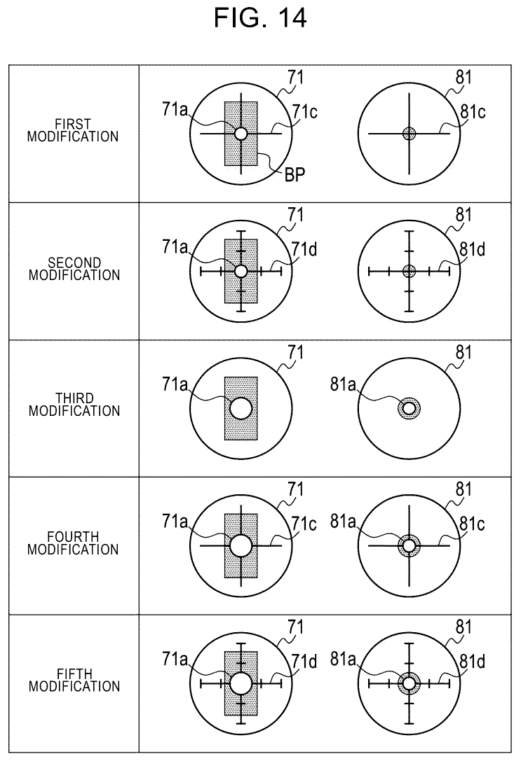

2.5 Modification of Targets Next, various modifications of the first target 71 and the second target 81 according to the first embodiment will be described. FIG. 14 shows first to fifth modifications of the first target 71 and the second target 81.

The first target 71 according to the first modification differs from the first target 71 according to the first embodiment only in that an indicator 71c indicating the position of the pinhole 71a is formed. The second target 81 according to the first modification differs from the second target 81 according to the first embodiment only in that an indicator 81c indicating the target position on which a part of the pulse laser light PL having passed through the pinhole 71a is radiated is formed. Each of the indicators 71c, 81c has a cross shape and is formed by a notch or a groove. The indicator 71c is an example of the “first indicator” according to the technology of the present disclosure. The indicator 81c is an example of the “second indicator” according to the technology of the present disclosure.

The first target 71 according to the second modification differs from the first target 71 according to the first embodiment only in that a graduated indicator 71d is formed. The second target 81 according to the second modification differs from the second target 81 according to the first embodiment only in that a graduated indicator 81d is formed. The indicators 71d, 81d are similar to the indicators 71c, 81c according to the first modification except that they have graduations.

The second target 81 according to the third modification differs from the second target 81 according to the first embodiment only in that a pinhole 81a is formed at the target position on which a part of the pulse laser light PL having passed through the pinhole 71a is radiated. In the first target 71 according to the third modification, the diameter of the pinhole 71a is larger than the diameter of the pinhole 81a of the second target 81. For example, when the diameter of the pinhole 81a is 1 mm, the diameter of the pinhole 71a is 2 mm. A part of the pulse laser light PL having passed through the pinhole 71a of the first target 71 is radiated on a region including the pinhole 81a of the second target 81. The pinhole 81a is an example of the “second passage hole” according to the technology of the present disclosure.

The first target 71 according to the fourth modification differs from the first target 71 according to the third modification only in that an indicator 71c similar to that of the first modification is further formed. The second target 81 according to the fourth modification differs from the second target 81 according to the third modification only in that an indicator 81c similar to that of the first modification is further formed.

The first target 71 according to the fifth modification differs from the first target 71 according to the third modification only in that a graduated indicator 71d similar to that of the second modification is further formed. The second target 81 according to the fifth modification differs from the second target 81 according to the third modification only in that a graduated indicator 81d similar to that of the second modification is further formed.

According to the first to fifth modifications, the irradiation positions of the pulse laser light PL on the first target 71 and the second target 81 can be checked more accurately than in the first embodiment, so that alignment adjustment can be performed more accurately.

Here, the indicators 71c, 81c, 71d, 81d are not limited to have a cross shape, and may have a shape such as a Y shape, a star shape, a shape in which a plurality of straight lines extend radially from one point, and a plurality of similar polygons having the same center.

### 3. Second Embodiment

The laser device 2 according to a second embodiment of the present disclosure will be described. Any component same as that described above is denoted by an identical reference sign, and duplicate description thereof is omitted unless specific description is needed.

### 3.1 Configuration

The laser device 2 according to the present embodiment has a configuration similar to that of the laser device 2 according to the comparative example except for the pulse extension system.

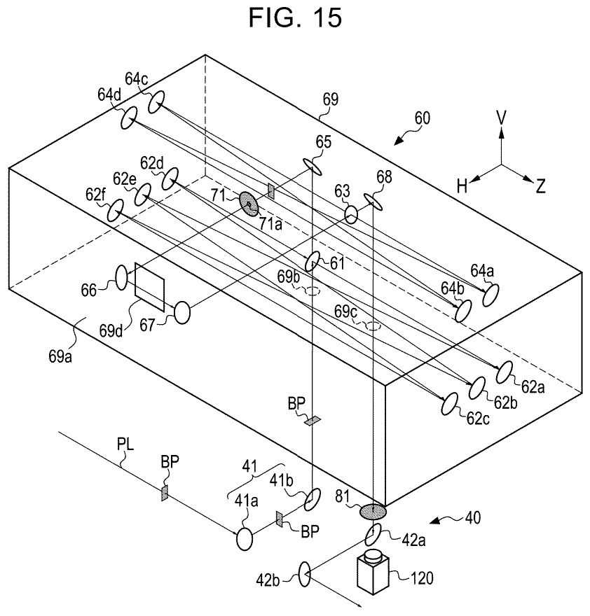

FIG. 15 is a view of the pulse width extension system according to the second embodiment viewed obliquely from above. The pulse width extension system according to the present embodiment differs from the first embodiment in the position at which the second target 81 is arranged. Specifically, in the present embodiment, the second target 81 is arranged so as to be retractable from the optical path between the high reflection mirror 68 and the high reflection mirror 42a. For example, the second target 81 is arranged in an optical path pipe outside the case 69 connected to the opening 69c and close to the high reflection mirror 42a.

In the present embodiment as well, the first target 71 and the second target 81 are configured to be movable by the target moving mechanism. An individual target moving mechanism may be provided for each of the first target 71 and the second target 81. As for the target moving mechanism, any of a collapsable type, a slide movement type, a rotation type, and the like can be applied as in the first embodiment and the modifications.

### 3.2 Operation

Operation of the laser device 2 according to the present embodiment with respect to the output of the pulse laser light PL is similar to that of the comparative example. Further, operation related to alignment adjustment of the optical axis according to the present embodiment is similar to that of the first embodiment.

In the present embodiment, for the first target 71, the operator adjusts the first steering unit 41 while observing the first target 71 visually via the window 60a or by using the camera 100 as in the first embodiment.

On the other hand, for the second target 81, since it is difficult for the operator to visually observe the second target 81, it is preferable to adjust the first steering unit 41 while observing the second target 81 using a camera 120. Specifically, the camera 120 is arranged at a position facing the second target 81 with the high reflection mirror 42a interposed therebetween. The high reflection mirror 42a has a property of transmitting visible light. The camera 120 receives the fluorescence emitted by the second target 81 via the high reflection mirror 42a, and thereby images the second target 81. The camera 120 may be arranged so as to image the second target 81 from the outside of the optical path pipe via a window provided in the optical path pipe.

### 3.3 Effect

In the present embodiment, since the distance between the first target 71 and the second target 81 is longer than that in the first embodiment, angle adjustment of the optical axis can be performed more accurately.

### 4. Third Embodiment

The laser device 2 according to a third embodiment of the present disclosure will be described. Any component same as that described above is denoted by an identical reference sign, and duplicate description thereof is omitted unless specific description is needed.

### 4.1 Configuration

The laser device 2 according to the present embodiment has a configuration similar to that of the laser device 2 according to the comparative example except for the pulse extension system.

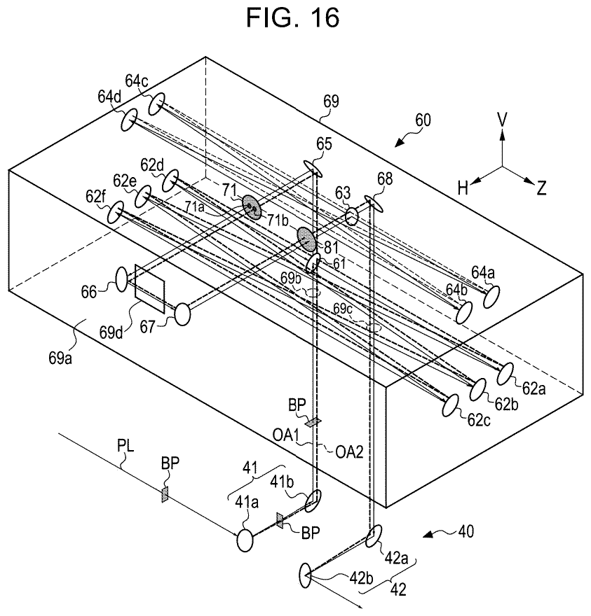

FIG. 16 is a view of the pulse width extension system according to the third embodiment viewed obliquely from above. The pulse width extension system according to the present embodiment differs from the first embodiment only in the configuration of the first target 71. In the present embodiment, the first target 71 is provided with two pinholes 71a, 71b.

Since optical elements configuring the L-OPS 60 are gradually deteriorated by being irradiated with the pulse laser light PL, the optical axis may be changed in order to extend the usage lifetime. The optical axis in the L-OPS 60 is changed by adjusting the first steering unit 41. Further, the second steering unit 42 is adjusted so that the output optical path of the pulse laser light PL output from the PO beam steering unit 40 does not change due to the change of the optical axis in the L-OPS 60.

FIG. 16 shows a first optical axis OA1 before the change and a second optical axis OA2 after the change. In the L-OPS 60, the first optical axis OA1 and the second optical axis OA2 are substantially parallel to each other. For example, the first optical axis OA1 can be changed to the second optical axis OA2 by rotating the high reflection mirror 41a about the V axis to tilt the first optical axis OA1 in the Z-axis direction and then rotating the high reflection mirror 41b. Further, the second optical axis OA2 coincides with the position of the first optical axis OA1 at the high reflection mirror 42b by rotating the high reflection mirror 42a, and the second optical axis is aligned with the output optical path by rotating the high reflection mirror 42b about the V axis.

By changing from the first optical axis OA1 to the second optical axis OA2 in this way, it is possible to change the incident positions of the pulse laser light PL on the respective optical elements configuring the L-OPS 60. By operating the laser device 2 using the first optical axis OA1 and changing it to the second optical axis OA2 when deterioration of the respective optical elements occurs, it is possible to extend the usage lifetime of the L-OPS 60.

The pinholes 71a, 71b of the first target 71 are provided at positions separated from each other by a length corresponding to the distance between the first optical axis OA1 and the second optical axis OA2. The second target 81 has a configuration similar to that of the first embodiment.

Similarly to the first embodiment, the first target 71 and the second target 81 are configured to be movable by the target moving mechanism. As for the target moving mechanism, any of a collapsable type, a slide movement type, a rotation type, and the like can be applied as in the first embodiment and the modifications. When the first target 71 is arranged on the optical path by the target moving mechanism, the pinhole 71a is arranged at a position through which the first optical axis OA1 passes, and the pinhole 71b is arranged at a position through which the second optical axis OA2 passes.

### 4.2 Operation

Operation of the laser device 2 according to the present embodiment with respect to the output of the pulse laser light PL is similar to that of the comparative example except that changing from the first optical axis OA1 to the second optical axis OA2 is performed in accordance with deterioration of the L-OPS 60. In the present embodiment, alignment adjustment can be performed in both a case in which either of the first optical axis OA1 and a case in which the second optical axis OA2 is used.

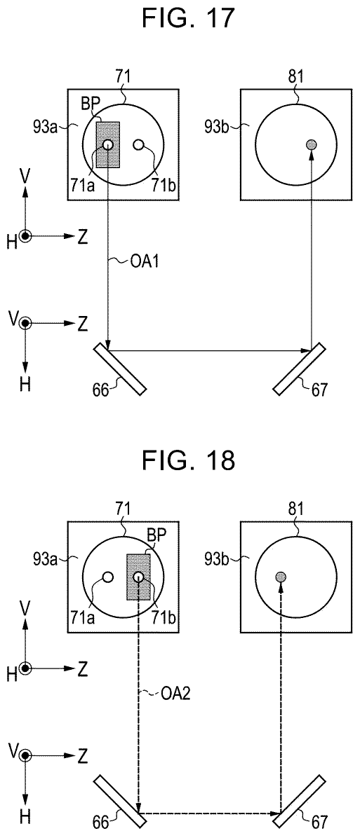

When the first optical axis OA1 is used, as shown in FIG. 17, the operator adjusts the first steering unit 41 so that the center of the irradiation region coincides with the pinhole 71a, and checks the position on which the pulse laser light PL having passed through the pinhole 71a is radiated at the second target 81. When the irradiation position does not coincide with the target position of the second target 81, the operator adjusts the first steering unit 41 so as to coincide therewith. In this case, the target position is a position at which the designed optical axis of the first optical axis OA1 passes through the second target 81.

On the other hand, when the second optical axis OA2 is used, as shown in FIG. 18, the operator adjusts the first steering unit 41 so that the center of the irradiation region coincides with the pinhole 71b, and checks the position on which the pulse laser light PL having passed through the pinhole 71b is radiated at the second target 81. When the irradiation position does not coincide with the target position of the second target 81, the operator adjusts the first steering unit 41 so as to coincide therewith. In this case, the target position is a position at which the designed optical axis of the second optical axis OA2 passes through the second target 81.

### 4.3 Effect

According to the present embodiment, alignment adjustment can be accurately performed even when the optical axis is changed in order to extend the usage lifetime of the L-OPS 60. Further, as in the first embodiment, alignment adjustment can be completed in a short time.

In the third embodiment, the optical axis of the L-OPS 60 can be set to two positions, but may be set to three or more positions. That is, three or more pinholes may be provided in the first target 71 in accordance with three or more positions to which the optical axis is set.

### 4.4 Modification of Targets

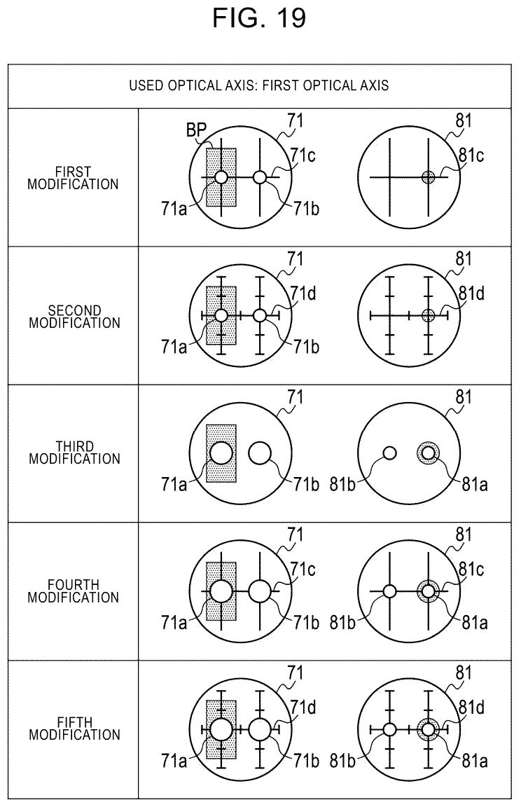

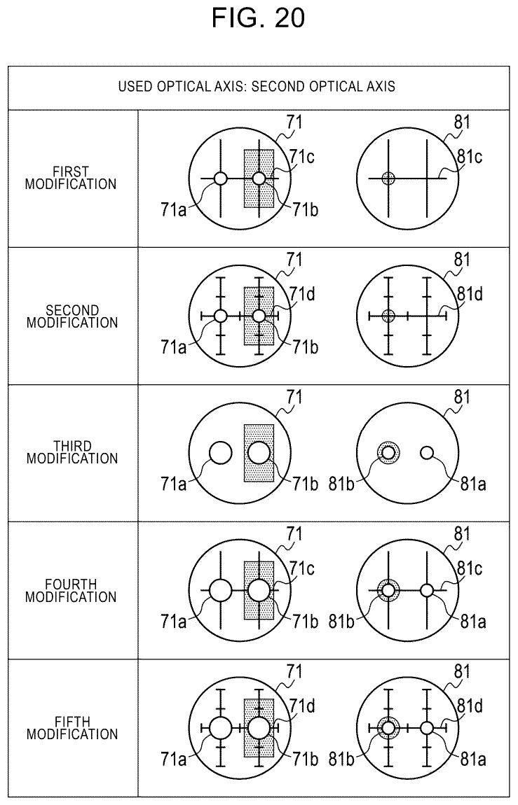

Next, various modifications of the first target 71 and the second target 81 according to the third embodiment will be described. FIGS. 19 and 20 show first to fifth modifications of the first target 71 and the second target 81. FIG. 19 shows the irradiation region when the first optical axis OA1 is used. FIG. 20 shows the irradiation region when the second optical axis OA2 is used.

The first target 71 according to the first modification differs from the first target 71 according to the third embodiment only in that an indicator 71c indicating the positions of the pinholes 71a, 71b is provided. The second target 81 according to the first modification differs from the second target 81 according to the third embodiment only in that an indicator 81c indicating the respective target positions on which a part of the pulse laser light PL having passed through the pinholes 71a, 71b is radiated is formed. Each of the indicators 71c, 81c is formed by a notch or a groove.

The first target 71 according to the second modification differs from the first target 71 according to the third embodiment only in that a graduated indicator 71d indicating the positions of the pinholes 71a, 71b is provided. The second target 81 according to the second modification differs from the second target 81 according to the third embodiment only in that a graduated indicator 81d indicating the respective target positions on which a part of the pulse laser light PL having passed through the pinholes 71a, 71b is radiated is formed. The indicators 71d, 81d are similar to the indicators 71c, 81c according to the first modification except that they have graduations.

The second target 81 according to the third modification differs from the second target 81 according to the third embodiment only in that a pinhole 81a is formed at a target position of a position on which a part of the pulse laser light PL having passed through the pinhole 71a is radiated, and that a pinhole 81b is formed at a target position of a position on which a part of the pulse laser light PL having passed through the pinhole 71b is radiated. In the first target 71 according to the third modification, the diameter of each of the pinholes 71a, 71b is larger than the diameter of each of the pinholes 81a, 81b of the second target 81. For example, when the diameter of each of the pinholes 81a, 81b is 1 mm, the diameter of each of the pinholes 71a, 71b is 2 mm. A part of the pulse laser light PL having passed through the pinhole 71a of the first target 71 is radiated on a region including the pinhole 81a of the second target 81. A part of the pulse laser light PL having passed through the pinhole 71b of the first target 71 is radiated on a region including the pinhole 81b of the second target 81.

The first target 71 according to the fourth modification differs from the first target 71 according to the third modification only in that an indicator 71c similar to that of the first modification is further formed. The second target 81 according to the fourth modification differs from the second target 81 according to the third modification only in that an indicator 81c similar to that of the first modification is further formed.

The first target 71 according to the fifth modification differs from the first target 71 according to the third modification only in that a graduated indicator 71d similar to that of the second modification is further formed. The second target 81 according to the fifth modification differs from the second target 81 according to the third modification only in that a graduated indicator 81d similar to that of the second modification is further formed.

According to the first to fifth modifications, the irradiation positions of the pulse laser light PL on the first target 71 and the second target 81 can be checked more accurately than in the third embodiment, so that alignment adjustment can be performed more accurately.

Here, the indicators 71c, 81c, 71d, 81d are not limited to have a cross shape, and may have a shape such as a Y shape, a star shape, a shape in which a plurality of straight lines extend radially from one point, and a plurality of similar polygons having the same center.

### 5. Modification of First to Third Embodiments

Next, various modifications common to the first to third embodiments will be described. In the above embodiments, the shapes of the first target 71 and the second target 81 are circular, but the shapes are not limited to circular, and may be other shapes such as a triangle, a square, or the like. Further, the first target 71 and the second target 81 are not limited to those emitting fluorescence by being irradiated with the pulse laser light PL as long as a part irradiated with the pulse laser light PL can be determined.

In the above embodiments, two targets are arranged so as to be retractable from the optical path including the L-OPS 60, but only one target may be arranged so as to be retractable. In this case, a pinhole may not be provided in the target. Even when only one target is used, position adjustment of the optical axis can be performed as alignment adjustment.

### 6. Electronic Device Manufacturing Method

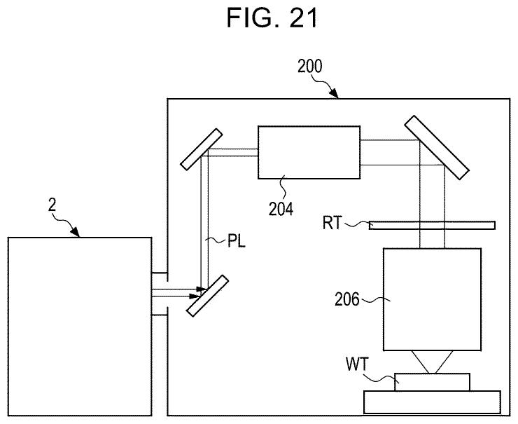

FIG. 21 schematically shows a configuration example of an exposure apparatus 200. The exposure apparatus 200 includes an illumination optical system 204 and a projection optical system 206. For example, the illumination optical system 204 illuminates a reticle pattern of a reticle (not shown) arranged on a reticle stage RT with the pulse laser light PL incident from the laser device 2. The projection optical system 206 causes the pulse laser light PL transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 200 synchronously translates the reticle stage RT and the workpiece table WT to expose the workpiece to the pulse laser light PL reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A pulse width extension system configured to output entering pulse laser light with a pulse width thereof extended, comprising:
a pulse width extension optical system including a beam splitter and a plurality of mirrors;
a case accommodating the pulse width extension optical system;
at least one target allowing a part thereof irradiated with the pulse laser light to be determined; and
a target moving mechanism capable of arranging the at least one target on an optical path of the pulse laser light including the pulse width extension optical system, and retracting the at least one target from the optical path.

2. The pulse width extension system according to claim 1,
wherein the plurality of mirrors configure a loop optical path that through which a part of the pulse laser light reflected by the beam splitter is circulated and returned to the beam splitter.

3. The pulse width extension system according to claim 1,
further comprising a steering device including a plurality of steering mirrors for adjusting alignment of an optical axis on which the pulse laser light enters the pulse width extension optical system.

4. The pulse width extension system according to claim 1,
wherein the at least one target emits fluorescence at the part irradiated with the pulse laser light.

5. The pulse width extension system according to claim 1,
wherein the target moving mechanism is capable of moving the at least one target between a collapsed state and a raised state.

6. The pulse width extension system according to claim 1,
wherein the target moving mechanism is capable of sliding the at least one target.

7. The pulse width extension system according to claim 1,
wherein the target moving mechanism is capable of rotating the at least one target.

8. The pulse width extension system according to claim 1,
wherein the at least one target is accommodated in the case, and
the case is formed with a window that allows the at least one target to be observed from outside of the case.

9. The pulse width extension system according to claim 8,
further comprising a camera for imaging the at least one target from the outside of the case via the window.

10. The pulse width extension system according to claim 1,
wherein the at least one target includes a first target and a second target,
the first target and the second target are movable by the target moving mechanism, and
the first target is arranged on an upstream side of the optical path with respect to the second target.

11. The pulse width extension system according to claim 10,
wherein the first target is formed with at least one first passage hole through which a part of the pulse laser light passes.

12. The pulse width extension system according to claim 11,
wherein the first target is formed with a first indicator indicating a position of the at least one first passage hole.

13. The pulse width extension system according to claim 12,
wherein the second target is formed with a second indicator indicating a target position on which a part of the pulse laser light having passed through the at least one first passage hole is radiated.

14. The pulse width extension system according to claim 11,
wherein the second target is formed with at least one second passage hole, and
a diameter of the at least one first passage hole is larger than a diameter of the at least one second passage hole.

15. The pulse width extension system according to claim 12,
wherein the second target is formed with a second indicator indicating a position of the at least one second passage hole.

16. A laser device comprising:
a laser oscillator configured to output pulse laser light; and
a pulse width extension system configured to output entering pulse laser light with a pulse width thereof extended,
the pulse width extension system including:
a pulse width extension optical system including a beam splitter and a plurality of mirrors;
a case accommodating the pulse width extension optical system;
at least one target allowing a part thereof irradiated with the pulse laser light to be determined; and
a target moving mechanism capable of arranging the at least one target on an optical path including the pulse width extension optical system, and retracting the at least one target from the optical path.

17. An electronic device manufacturing method comprising:
generating pulse laser light with pulse width extended using a laser device;
outputting the pulse laser light to an exposure apparatus; and
exposing a photosensitive substrate to the pulse laser light in the exposure apparatus to manufacture an electronic device,
the laser device including:
a laser oscillator configured to output the pulse laser light; and
a pulse width extension system configured to output entering pulse laser light with the pulse width thereof extended, and
the pulse width extension system including:
a pulse width extension optical system including a beam splitter and a plurality of mirrors;
a case accommodating the pulse width extension optical system;
at least one target allowing a part thereof irradiated with the pulse laser light to be determined; and
a target moving mechanism capable of arranging the at least one target on an optical path including the pulse width extension optical system, and retracting the at least one target from the optical path.
